(19) United States
(12) Patent Application Publication
(10) Pub. No.: US 2024/0379632 A1
(43) Pub. Date: Nov. 14, 2024

(54) Display Module Manufacturing Method And Display Module

(71) Applicant: Sony Group Corporation, Tokyo (JP)

(72) Inventors: Ippei Nishinaka, Kanagawa (JP); Kohei Kabuki, Tokyo (JP); Hisao Sakurai, Saitama (JP); Eizo Okamoto, Kanagawa (JP); Norifumi Kikuchi, Kanagawa (JP)

(73) Assignee: Sony Group Corporation, Tokyo (JP)

(21) Appl. No.: 18/692,441

(22) PCT Filed: Mar. 11, 2022
(86) PCT No.: PCT/JP2022/010849

§ 371 Date: Mar. 15, 2024

(30) Foreign Application Priority Data
Sep. 30, 2021 (JP) 2021-160659

(51) Int. Cl. H01L 25/075; H01L 27/12

(52) U.S. Cl. CPC H01L 25/0753; H01L 27/124

(57) ABSTRACT

The present technology relates to a display module manufacturing method and a display module that enable more suitable manufacturing of an LED display.

The display module manufacturing method according to the present technology includes: forming, on a glass substrate, a resin layer in which a plurality of light-emitting elements arranged in an array and first wiring for driving the light-emitting elements are formed; and joining, before or after peeling the glass substrate from the resin layer, a printed circuit board, on which second wiring for driving the light-emitting elements is formed, to a surface of the resin layer opposite to a light extraction surface. The present technology can be applied to, for example, a large direct-view LED display that displays video content.

### TECHNICAL FIELD

The present technology relates to a display module manufacturing method and a display module, and more particularly to a display module manufacturing method and a display module that enable more suitable manufacturing of a light-emitting diode (LED) display.

### BACKGROUND ART

In general, an LED display is formed by tiling a printed circuit board (PCB) substrate, on which LED chips are evenly arranged. The PCB substrate of the LED display has more layers and is costlier than a PCB substrate of a typical liquid crystal display.

In addition, it is generally known that the cost of the PCB substrate is increased as the wiring accuracy significantly increases. Therefore, it is difficult to mount a u-LED, which is being developed to reduce the cost of an LED, on the PCB substrate.

To solve these problems, the use of a glass substrate instead of a PCB substrate has been studied. For example, Patent Document 1 describes a technique for obtaining an electronic device by peeling a support substrate from a laminate that includes a glass-made support substrates, a polyimide resin substrate, and an electronic device member.

### CITATION LIST

### Patent Document

Patent Document 1: Japanese Patent Application Laid-Open No. 2021-2622

### SUMMARY OF THE INVENTION

### Problems to be Solved by the Invention

A technique for routing wiring to the back surface side of the glass substrate has not been established, making it difficult to manufacture an LED display by tiling the glass substrate. In addition, the glass substrate is more prone to breaking when physical force is applied than the PCB substrate, and hence the tiling of the glass substrate is not desirable.

The present technology has been developed in view of such a situation, and an object of the present technology is to enable more suitable manufacturing of an LED display.

### Solutions to Problems

A display module manufacturing method according to one aspect of the present technology includes: forming, on a glass substrate, a resin layer in which a plurality of light-emitting elements arranged in an array and first wiring for driving the light-emitting elements are formed; and joining, before or after peeling the glass substrate from the resin layer, a printed circuit board, on which second wiring for driving the light-emitting elements is formed, to a surface of the resin layer opposite to a light extraction surface.

A display module according to one aspect of the present technology is formed by: forming, on a glass substrate, a resin layer in which a plurality of light-emitting elements arranged in an array and first wiring for driving the light-emitting elements are formed; and joining, before or after peeling the glass substrate from the resin layer, a printed circuit board, on which second wiring for driving the light-emitting elements is formed, to a side of the resin layer opposite to a light extraction surface.

In one aspect of the present technology, a resin layer, in which a plurality of light-emitting elements arranged in an array and first wiring for driving the light-emitting elements are formed, is formed on a glass substrate, and then, before or after the glass substrate is peeled from the resin layer, a printed circuit board, on which second wiring for driving the light-emitting elements is formed, is joined to a surface of the resin layer opposite to a light extraction surface.

### BRIEF DESCRIPTION OF DRAWINGS

FIG. 1 is a view illustrating a configuration example of a display system including a tiling display.

FIG. 2 is a block diagram illustrating a detailed configuration example of a video wall controller and a display module.

FIG. 3 is a plan view illustrating a configuration of the display module.

FIG. 4 is an enlarged cross-sectional view of a part of the display module.

FIG. 5 is a view for explaining a display module manufacturing method.

FIG. 6 is a view for explaining the display module manufacturing method.

FIG. 7 is a view for explaining the display module manufacturing method.

FIG. 8 is a view for explaining the display module manufacturing method.

FIG. 9 is a view for explaining the display module manufacturing method.

FIG. 10 is an enlarged cross-sectional view of a part of a general display module.

FIG. 11 is an enlarged cross-sectional view illustrating a part of a display module using a glass substrate.

FIG. 12 is a view for comparing and explaining structures of the general display module, the display module using the glass substrate, and a display module according to the present technology.

FIG. 13 is a cross-sectional view illustrating a first modification of the display module.

FIG. 14 is a view illustrating a display module manufacturing method according to the first modification.

FIG. 15 is a cross-sectional view illustrating a second modification of the display module.

FIG. 16 is a view illustrating a display module manufacturing method according to the second modification.

FIG. 17 is a view illustrating a display module manufacturing method according to the second modification.

FIG. 18 is a cross-sectional view illustrating a third modification of the display module.

FIG. 19 is a view for describing a display module manufacturing method according to a third modification.

FIG. 20 is a view for describing the display module manufacturing method according to the third modification.

FIG. 21 is a cross-sectional view illustrating a modification of a laminate before being bonded to a PCB substrate.

### MODE FOR CARRYING OUT THE INVENTION

Hereinafter, modes for carrying out the present technology will be described. The description will be given in the following order.
1. Display System to Which Present Technology is Applicable
2. Structure of Display Module
3. Display Module Manufacturing Method
4. Modifications

### 1. Display System to Which Present Technology is Applicable

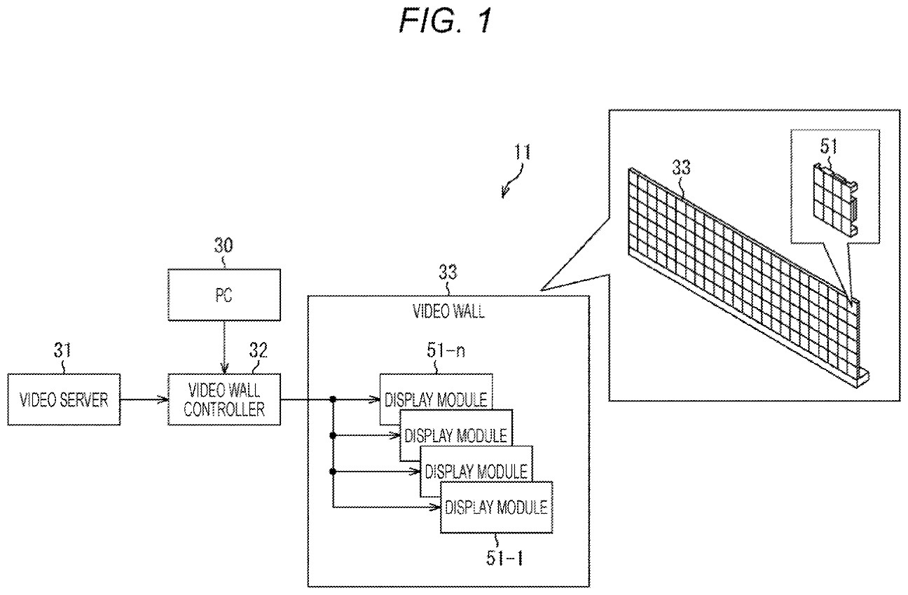

FIG. 1 is a view illustrating a configuration example of a display system including a tiling display as an example of a display system to which the present technology is applicable.

A display system 11 of FIG. 1 displays video content on, for example, a large direct-view LED display including a plurality of display modules arranged in a tile pattern.

The display system 11 includes a PC 30, a video server 31, a video wall controller 32, and a video wall 33.

The personal computer (PC) 30 is a general-purpose computer, which receives an operation input made by a user and supplies a command corresponding to the operation content to the video wall controller 32.

The video server 31 includes, for example, a server computer or the like, and supplies data of a video signal of video content or the like to the video wall controller 32.

The video wall controller 32 operates in response to the command supplied from the PC 30, and distributes the data including the video signal of the video content to display modules 51-1 to 51-n included in the video wall 33 to cause the display modules 51-1 to 51-n to display the data.

Hereinafter, the display modules 51-1 to 51-n will be simply referred to as a display module 51 in a case where the display modules 51-1 to 51-n are not required to be individually distinguished from each other.

As illustrated in the upper right part of FIG. 1, the video wall 33 is formed by arranging the display modules 51-1 to 51-n in the tile pattern, in which pixels including light emitting diodes (LEDs) are arranged in an array. In the video wall 33, images displayed by the individual display modules 51 are combined in the tile pattern, so that one image is displayed as the entire video wall 33.

Note that the video wall controller 32 and the video wall 33 may be integrated with each other, or may be integrated into a display device.

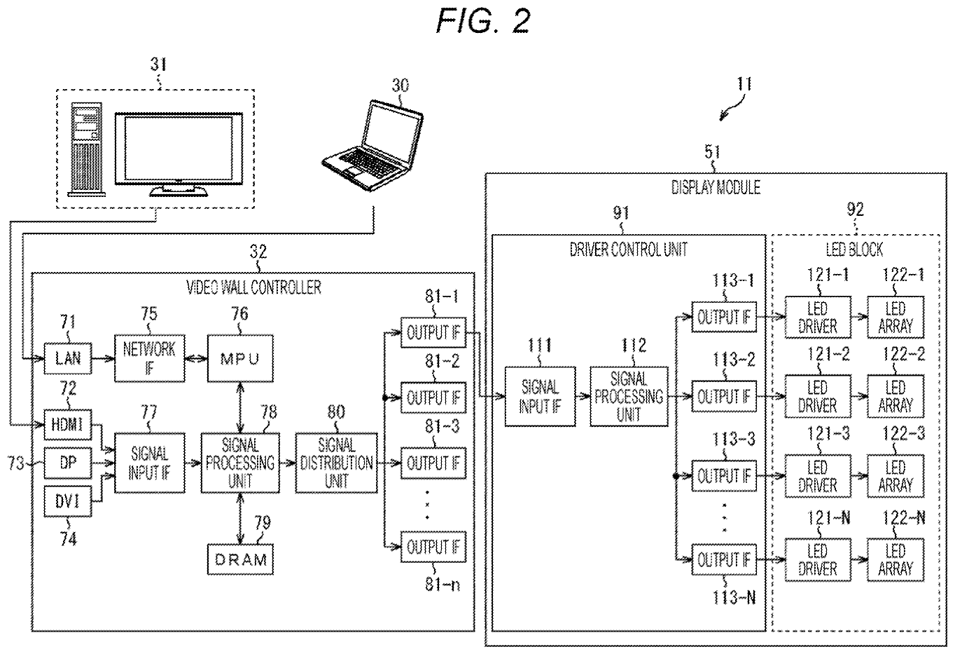

FIG. 2 is a block diagram illustrating a detailed configuration example of the video wall controller 32 and the display module 51.

The video wall controller 32 includes the respective terminals of a LAN terminal 71, an HDMI (registered trademark) terminal 72, a DP terminal 73, and a DVI terminal 74. Furthermore, the video wall controller 32 includes a network interface (IF) 75, an MPU 76, a signal input IF 77, a signal processing unit 78, a DRAM 79, a signal distribution unit 80, and output IFs 81-1 to 81-n.

The local area network (LAN) terminal 71 is, for example, a connection terminal such as a LAN cable. The LAN terminal 71 implements communication with the PC 30 that supplies a control command or the like corresponding to operation content of the user to the video wall controller 32, and supplies the input control command or the like to the MPU 76 via the network IF 75.

Note that the LAN terminal 71 may have a configuration adapted to physical connection with a wired LAN cable, or may have a configuration adapted to connection with a so-called wireless LAN implemented by wireless communication.

The micro processor unit (MPU) 76 receives the input of the control command supplied from the PC 30 via the LAN terminal 71 and the network IF 75, and supplies a control signal corresponding to the control command to the signal processing unit 78.

Each of the high definition multimedia interface (HDMI) terminal 72, the display port (DP) terminal 73, and the digital visual interface (DVI) terminal 74 is an input terminal for data including the video signal. The HDMI terminal 72, the DP terminal 73, and the DVI terminal 74 are connected to the server computer that functions as the video server 31, and supply the data including the video signal to the signal processing unit 78 via the signal input IF 77. Note that the video wall controller 32 may include an input terminal based on another standard, such as a serial digital interface (SDI) terminal.

Although FIG. 2 illustrates an example in which the video server 31 and the HDMI terminal 72 are connected, any one of the HDMI terminal 72, the DP terminal 73, or the DVI terminal 74 may be selected and connected as necessary because the HDMI terminal 72, the DP terminal 73, and the DVI terminal 74 are different only in standards and basically have similar functions.

The signal processing unit 78 adjusts color temperature, contrast, brightness, and the like of the data including the video signal supplied via the signal input IF 77 on the basis of the control signal supplied from the MPU 76, and supplies the data to the signal distribution unit 80. At this time, as necessary, the signal processing unit 78 develops the data including the video signal using the connected dynamic random access memory (DRAM) 79, executes signal processing based on the control signal, and supplies a result of the signal processing to the signal distribution unit 80.

The signal distribution unit 80 distributes the data including the video signal, which has been subject to the signal processing and supplied from the signal processing unit 78, and individually distributes the data to the display modules 51-1 to 51-n via the output IFs 81-1 to 81-n.

The display module 51 includes a driver control unit 91 and an LED block 92.

The driver control unit 91 supplies data including a video signal for controlling light emission of LEDs included in LED arrays 122-1 to 122-N to a plurality of LED drivers 121-1 to 121-N included in the LED block 92.

The driver control unit 91 includes a signal input IF 111, a signal processing unit 112, and output IFs 113-1 to 113-N.

The signal input IF 111 receives the input of the data of the video signal supplied from the video wall controller 32, and supplies the data to the signal processing unit 112.

The signal processing unit 112 corrects the color and luminance of each of the display modules 51 on the basis of the data of the video signal supplied from the signal input IF 111, and generates data for setting light emission intensity of each of the LEDs included in the LED arrays 122-1 to 122-N. The generated data is distributed to the LED drivers 121-1 to 121-N of the LED block 92 via the output IFs 113-1 to 113-N.

The LED block 92 includes the LED drivers 121-1 to 121-N and the LED arrays 122-1 to 122-N.

Hereinafter, the LED drivers 121-1 to 121-N will be simply referred to as an LED driver 121 in a case where the LED drivers 121-1 to 121-N are not required to be individually distinguished from each other, and the LED arrays 122-1 to 122-N will be simply referred to as an LED array 122 in a case where the LED arrays 122-1 to 122-N are not required to be individually distinguished from each other.

The LED driver 121 drives the LEDs arranged in the corresponding LED array 122 on the basis of the data for setting the light emission intensity of the LEDs supplied from the driver control unit 91, and performs pulse width modulation (PWM) control of light emission.

### 2. Structure of Display Module

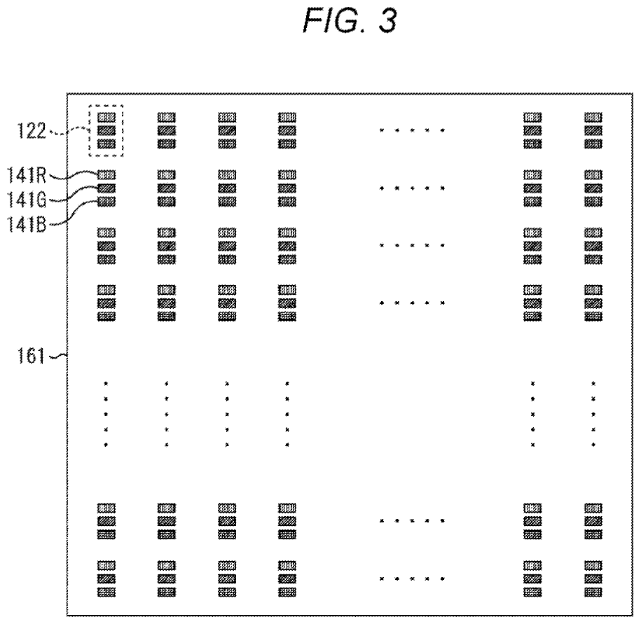

FIG. 3 is a plan view illustrating the configuration of the display module 51.

As illustrated in FIG. 3, the display module 51 is formed by arranging the LED arrays 122 in an array on the front surface of a printed circuit board (PCB) substrate 161. Each of the LED arrays 122 is included in a pixel in the display module 51.

In the LED array 122, LED chips 141R, 141G, 141B including u-LEDs, which are micrometer ultra-small LEDs, are mounted. The u-LEDs (micro-LEDs) included in the LED chips 141R, 141G, 141B are light-emitting elements that emit red, green, and blue light, respectively. The red, blue, and green LEDs are included in RGB subpixels that are included in pixels in the display module 51.

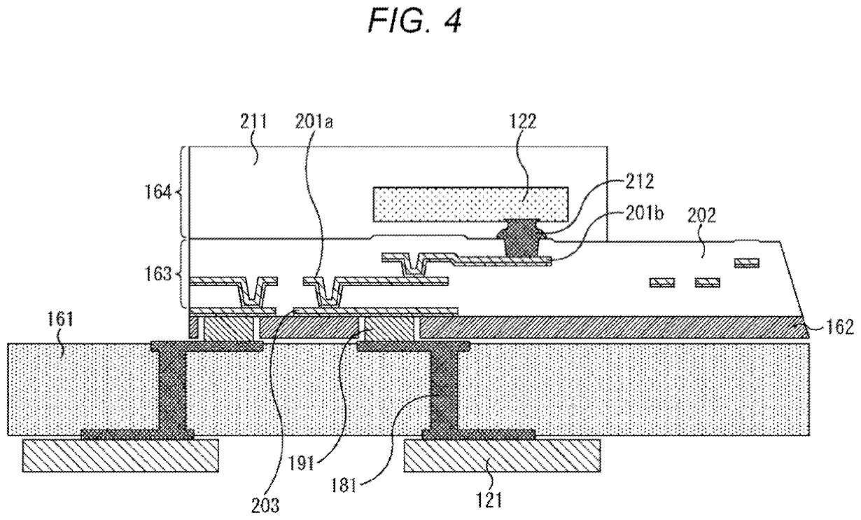

Next, a detailed structure of the display module 51 will be described with reference to FIG. 4. FIG. 4 is an enlarged cross-sectional view of a part of the display module 51.

As illustrated in FIG. 4, the display module 51 is formed by laminating a PCB substrate 161, a support substrate 162, a multilayer wiring layer 163, and an element layer 164.

The PCB substrate 161 includes, for example, a two-layer through substrate formed using glass epoxy. In the PCB substrate 161, a through electrode 181 penetrating the PCB substrate 161 is formed. The through electrode 181 connects circuits and components, provided in the multilayer wiring layer 163 and the element layer 164, to the LED driver 121 provided on the lower surface side of the PCB substrate 161. As the LED driver 121, for example, a Si-Driver is used.

As the support substrate 162, a film such as polyethylene terephthalate (PET) is used. A connection conductor 191 that connects the through electrode 181 and the signal pad 203 formed in the multilayer wiring layer 163 is embedded in the support substrate 162. The connection conductor 191 functions as a through electrode that electrically connects the PCB substrate 161 and the multilayer wiring layer 163.

The multilayer wiring layer 163 includes: a plurality of wiring layers including a wiring layer 201a on the PCB substrate 161 side and a wiring layer 201b on the element layer 164 side; and a resin 202 formed to seal each wiring layer. The plurality of wiring layers each includes, for example, a circuit using a thin film transistor (TFT) and wiring. The TFT is formed using, for example, low temperature polycrystalline silicon (LTPS). A signal pad 203 is formed on the lower surface (the surface on the PCB substrate 161 side) of the wiring layer 201b.

Note that, in the example of FIG. 4, the multilayer wiring layer 163 includes two wiring layers, but the number of wiring layers included in the multilayer wiring layer 163 can be any number according to the circuit scale.

The element layer 164 is formed by sealing the LED array 122 with a sealing film 211 of resin or the like. The light extraction surface, from which the light of each of the LEDs included in the LED array 122 is emitted, is the surface of the display module 51 on the element layer 164 side. An electrode 212 for connecting the LED array 122 and the wiring layer 201b is formed between the LED array 122 and the wiring layer 201b.

As described above, the display module 51 is formed by joining the resin layer to the PCB substrate 161 in which the through electrode 181 for driving the LEDs is formed via the support substrate 162, the resin layer including the multilayer wiring layer 163, which is provided with the wiring for driving the LEDs included in the LED array 122, and the element layer 164 in which the LED array 122 is formed.

### 3. Display Module Manufacturing Method

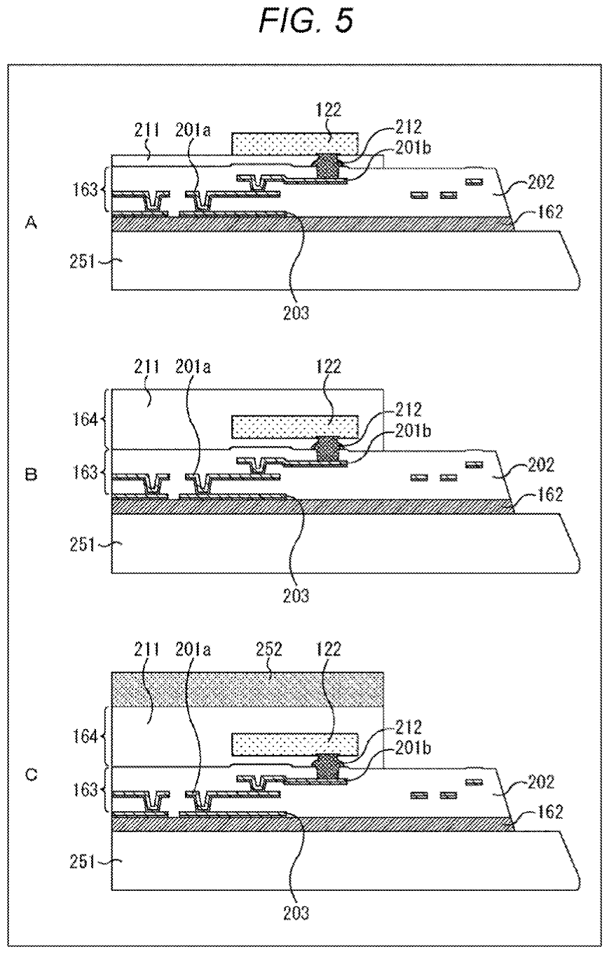

Next, a method for manufacturing the display module 51 will be described with reference to FIGS. 5 to 9.

First, as illustrated in A of FIG. 5, the support substrate 162 is formed on a glass substrate 251, and the multilayer wiring layer 163 is formed on the support substrate 162. The electrode 212 is formed to be partially exposed from the upper surface of the multilayer wiring layer 163 and connected to the wiring layer 201b, and the sealing film 211 is formed, whereby the multilayer wiring layer 163 is planarized. The LED array 122 is formed on the sealing film 211 to be connected to the electrode 212.

Next, as illustrated in B of FIG. 5, the LED array 122 is sealed by the sealing film 211. Note that the structure of a laminate, which includes the glass substrate, the support substrate, and the multilayer wiring layer, is the same as the structure used in a flexible organic LED (OLED) display or the like. The structure of a laminate, which includes the glass substrate 251, the support substrate 162, the multilayer wiring layer 163, and the element layer 164 according to the present technology, is a structure having the LED array 122 mounted on the multilayer wiring layer 163 instead of having an organic electro-luminescence (EL) film disposed on the multilayer wiring layer.

Next, as illustrated in C of FIG. 5, an adhesive 252 for fixing the support substrate is applied onto the element layer 164. Note that a water-soluble material is desirably used as the adhesive 252.

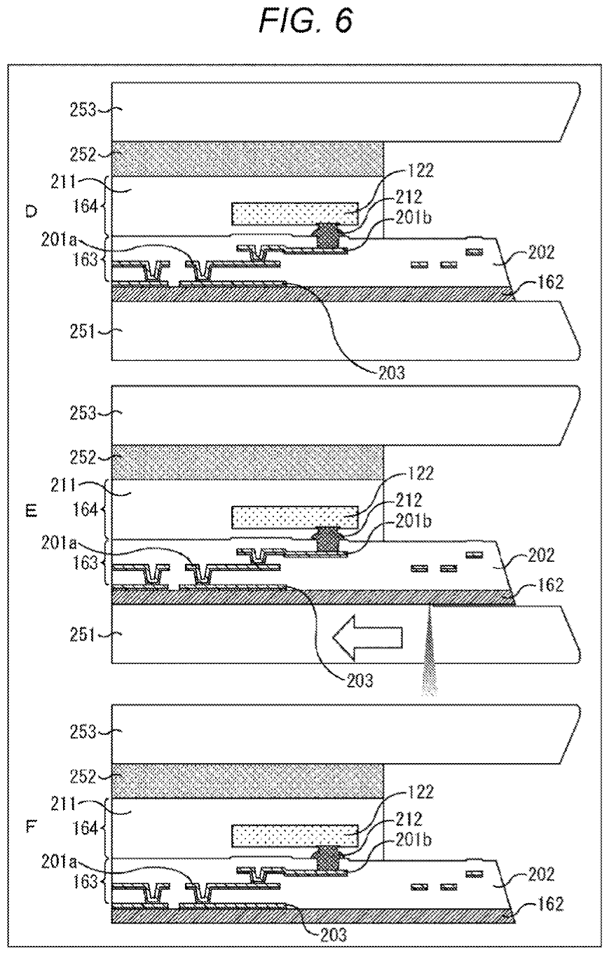

Subsequently, as illustrated in D of FIG. 6, a support substrate 253 and the element layer 164 are bonded to each other via the adhesive 252. For example, a vacuum laminator is used to bond the support substrate 253 and the element layer 164. Here, as the support substrate 253, for example, a glass substrate or a PET film is used. Considering the subsequent process of bonding the PCB substrate 161 and the support substrate 162, it is desirable to use a glass substrate as the support substrate 253.

Next, as illustrated in E of FIG. 6, a laminate, which includes the glass substrate 251, the support substrate 162, the multilayer wiring layer 163, the element layer 164, and the support substrate 253, is irradiated with a laser beam from the glass substrate 251 side. The laser beam passes through the glass substrate 251, and the support substrate 162 (the interface between the support substrate 162 and the glass substrate 251) is irradiated with the laser beam. A gap is formed between the support substrate 162 and the glass substrate 251 by the irradiation with the laser beam.

For example, by the irradiation of the entire support substrate 162 with the laser beam, the glass substrate 251 is peeled from the support substrate 162, as illustrated in F of FIG. 6. As a method of peeling the glass substrate 251, it is common to use laser lift off (LLO) that performs irradiation with a laser beam as described above, but the glass substrate 251 may be peeled using another method.

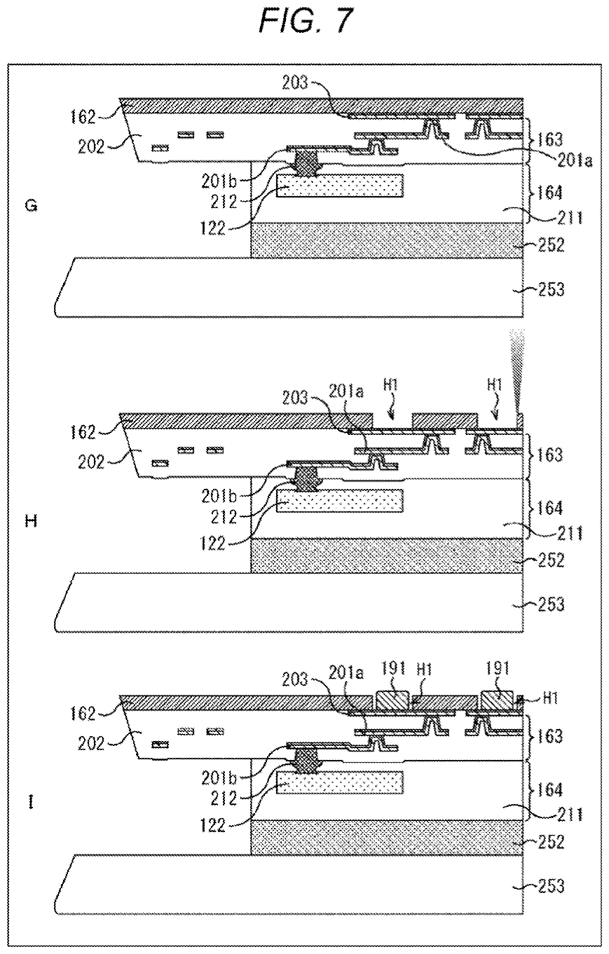

Subsequently, as illustrated in G of FIG. 7, a laminate, which includes the support substrate 162, the multilayer wiring layer 163, the element layer 164, and the support substrate 253, is disposed upside down.

Next, as illustrated in H of FIG. 7, the laminate is irradiated with a laser beam from the support substrate 162 side. An opening H1 is formed in the support substrate 162 by the irradiation with the laser beam. The irradiation with the laser beam is performed until a signal pad 203 of the multilayer wiring layer 163 is exposed, and the opening H1 is formed to have, for example, a rectangular cross section.

Next, as illustrated in I of FIG. 7, the connection conductor 191 is applied to the opening H1. The connection conductor 191 is formed using a material such as solder, an anisotropic conductive paste, an anisotropic conductive adhesive, or another conductive joining member. The material of the connection conductor 191 is determined on the basis of pressurization condition constraints in the subsequent process of joining the PCB substrate 161 and the support substrate 162.

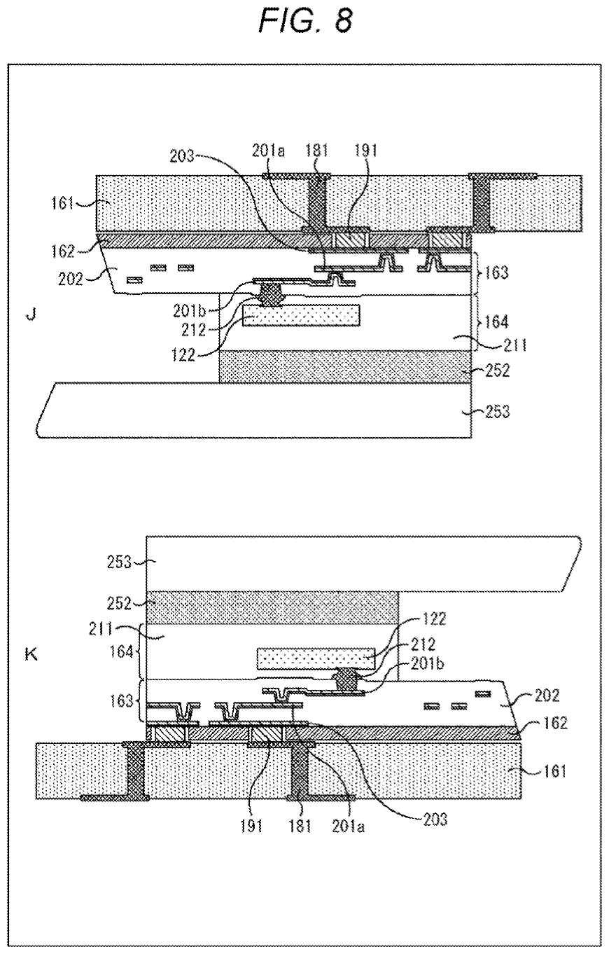

Subsequently, as illustrated in J of FIG. 8, the PCB substrate 161, in which the through electrode 181 is formed, and the support substrate 162 are bonded to each other. The PCB substrate 161 and the support substrate 162 are bonded to each other by a method corresponding to the material of the connection conductor 191, such as reflow or pressurization.

Next, as illustrated in K of FIG. 8, a laminate, which includes the PCB substrate 161, the support substrate 162, the multilayer wiring layer 163, the element layer 164, and the support substrate 253, is disposed upside down.

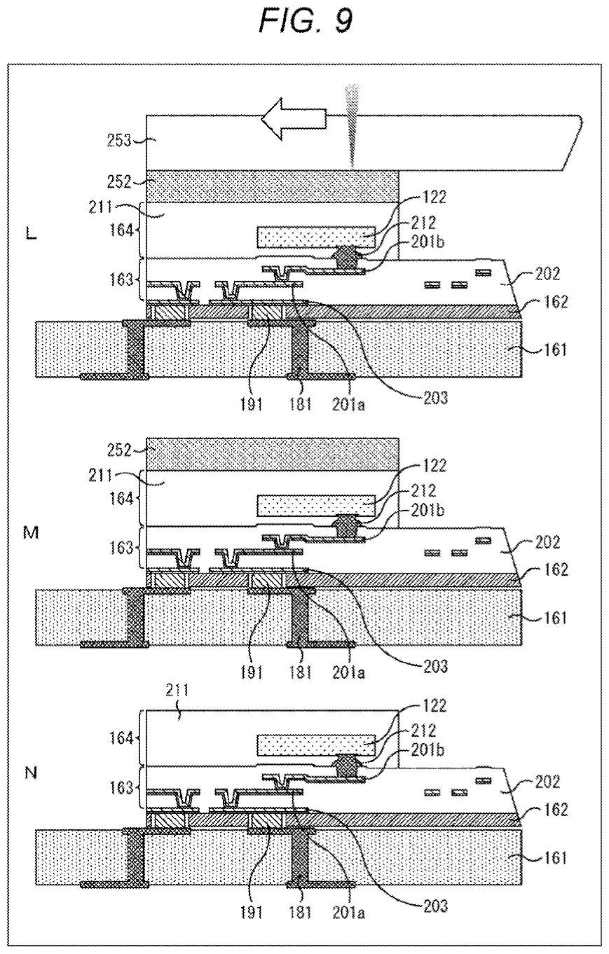

Subsequently, as illustrated in L of FIG. 9, a laser beam, with which the laminate is irradiated from the support substrate 253 side, passes through the support substrate 253, and the adhesive 252 (the interface between the adhesive 252 and the support substrate 253) is irradiated with the laser beam.

For example, by the irradiation of the entire adhesive 252 with the laser beam, the support substrate 253 is peeled from the adhesive 252, as illustrated in M of FIG. 9. As a method of peeling the support substrate 253, the LLO described above is generally used, but the support substrate 253 may be peeled using another method.

Then, as illustrated in N of FIG. 9, the adhesive 252 is removed by, for example, washing with water. Thereafter, the LED driver 121 and the like are formed on the lower surface side of the PCB substrate 161. Note that the LED driver 121 may be formed in advance on the PCB substrate 161 before the PCB substrate 161 and the support substrate 162 are bonded to each other. As described above, the display module 51 is completed.

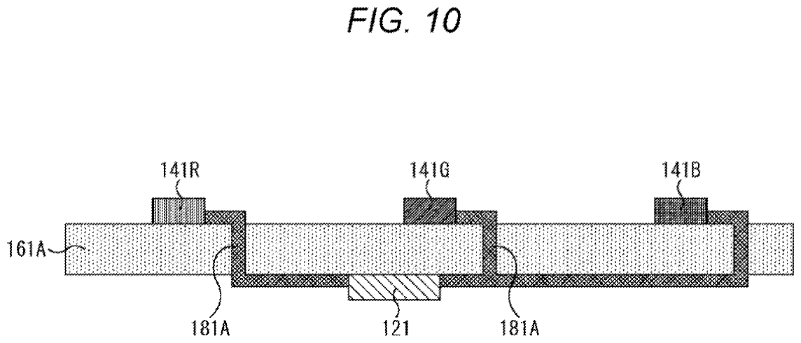

A detailed structure of a general display module will be described with reference to FIG. 10. FIG. 10 is an enlarged cross-sectional view of a part of the general display module.

As illustrated in FIG. 10, the general display module is formed by arranging the LED chips 141R, 141G, 141B on the upper surface of the PCB substrate 161A, and disposing the LED driver 121 on the lower surface of a PCB substrate 161A. A through electrode 181A penetrating the PCB substrate 161 is formed on the PCB substrate 161A. The through electrode 181A connects the LED chips 141R, 141G, 141B and the LED driver 121.

The PCB substrate 161A used for such a display module has more layers and is costlier than the PCB substrate used for a general liquid crystal display. In addition, it is generally known that the cost of the PCB substrate 161A significantly increases as the wiring accuracy is increased. Therefore, from a cost perspective, it is difficult to mount the LED chips 141R, 141G, 141B, which include μ-LEDs being developed to reduce the cost of LEDs, on the PCB substrate 161A.

To solve these problems, the use of a glass substrate instead of the PCB substrate 161A has been studied. In general, a glass substrate is less expensive than a PCB substrate, and has better wiring accuracy than the PCB substrates. In addition, a circuit using a TFT can be formed on the LED chip side of the glass substrate, so that it is expected to achieve a reduction in the cost of the display module by making the LED driver provided on the glass substrate inexpensive or by other means.

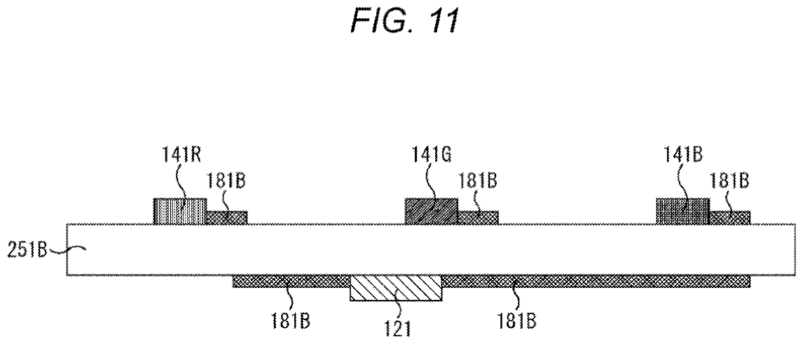

However, as illustrated in FIG. 11, in a case where the LED chips 141R, 141G, 141B are arranged on the upper surface of the glass substrate 251B, and the LED driver 121 is disposed on the lower surface of the glass substrate 251B, it is difficult to form wiring 181B, which connects the LED chips 141R, 141G, 141B and the LED driver 121, by penetrating the glass substrate 251B. In this case, for example, the wiring 181B is formed along the front surface or the side surface of the glass substrate 251B, but forming the wiring 181B on the side surface of the glass substrate 251B is not desirable for tiling the glass substrate 251B.

As described above, since a technique for routing the wiring to the back surface side of the glass substrate has not been established, it has been difficult to manufacture the LED display by tiling the glass substrate 251B. In addition, the glass substrate 251B is more prone to breaking when physical force is applied than the PCB substrate 161A, and hence the tiling of the glass substrate 251B is not desirable.

The display module 51 according to the present technology is manufactured by forming a laminate, which includes the support substrate 162, the multilayer wiring layer 163, and the element layer 164 on the glass substrate 251, peeling the glass substrate 251 from the laminate, and then joining the laminate and the PCB substrate 161.

Since a circuit using a TFT and wiring can be formed in the multilayer wiring layer 163 on the glass substrate 251, it is possible to reduce the wiring formed on the PCB substrate 161. This results in a reduced number of layers in the PCB substrate 161, thereby enabling a reduction in the cost of the substrate to be achieved. In addition, since the glass substrate 251 is not included in the final structure of the display module 51, there is no need to consider the problem of breakage in the glass substrate 251.

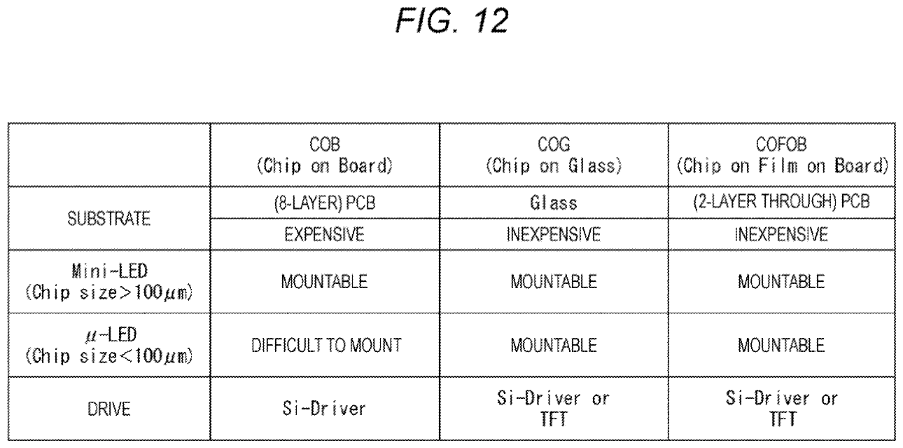

FIG. 12 is a view for comparing and explaining the structures of the general display module, a display module using a glass substrate, and a display module 51 according to the present technology.

The structure of the general display module is called a chip on board (COB), and the structure of the display module using a glass substrate is called a chip on glass (COG). The structure of the display module 51 according to the present technology is called chip on film on board (COFOB).

In the COB, an expensive eight-layer PCB substrate is used as a substrate. For example, it is possible from a cost perspective to mount a Mini-LED with a chip size of 100 μm or more, but it is difficult from a cost perspective to mount a μ-LED with a chip size of less than 100 μm because the cost of the PCB substrate increases as the wiring accuracy is increased. In addition, the LED is driven using a Si-Driver.

In the COG, an inexpensive glass substrate is used as a substrate. Since the glass substrate has better wiring accuracy than the PCB substrate, it is possible to mount either the Mini-LED or the μ-LED. In addition, the LED is driven using a Si-Driver or a TFT.

In the COFOB, an inexpensive two-layer penetrating PCB substrate is used as a substrate. Since the LED is mounted on the glass substrate 251 with good wiring accuracy, it is possible to mount either the Mini-LED or the μ-LED. In addition, since the circuit using the TFT is formed on the glass substrate 251 having good wiring accuracy, the LED can be driven using a Si-Driver or a TFT.

Therefore, in the present technology, a reduction in the cost of the display module 51 can be achieved by making the LED driver provided on the PCB substrate 161 inexpensive or by mounting the μ-LED that is less expensive than the Mini-LED.

### 4. Modifications

Example in which Double-Sided Electrode Structure is Formed On Support Substrate 162

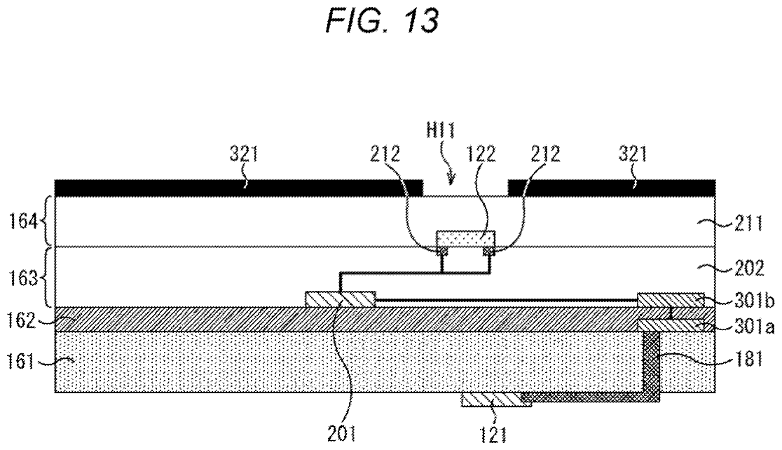

FIG. 13 is a cross-sectional view illustrating a first modification of the display module 51.

In the structure of the display module 51 described with reference to FIG. 4 and the like, the connection conductor 191 has been embedded in the opening H1 formed in the support substrate 162. In contrast, in the display module 51 according to the first modification of FIG. 13, a signal pad 301a connected to the through electrode 181 is formed on the lower surface of the support substrate 162, and a signal pad 301b connected to the wiring layer 201 is formed on the support substrate 162. In the support substrate 162, the signal pad 301a and the signal pad 301b are connected via wiring.

In addition, in the display module 51 according to the first modification of FIG. 13, a black layer 321 (light absorbing layer) is formed on the element layer 164. The black layer 321 is formed on the light extraction surface side of the display module 51 and has a function of absorbing external light applied from the outside. For example, the black layer 321 includes resin such as a resin, or a black light absorbing material such as carbon nanotube or urethane foam.

In the black layer 321, an opening H11 is formed to emit the light of each of the LEDs included in the LED array 122 to the light extraction surface side. The opening H11 is formed at a position corresponding to the LED array 122 of the element layer 164.

Note that, the example of FIG. 13, one wiring layer 201, the electrode 212, and the wiring that connects those are simply illustrated as the structure formed in the multilayer wiring layer 163, but in reality, a plurality of wiring layers is formed in the multilayer wiring layer 163, as in the example of FIG. 4. The same applies to the following drawings.

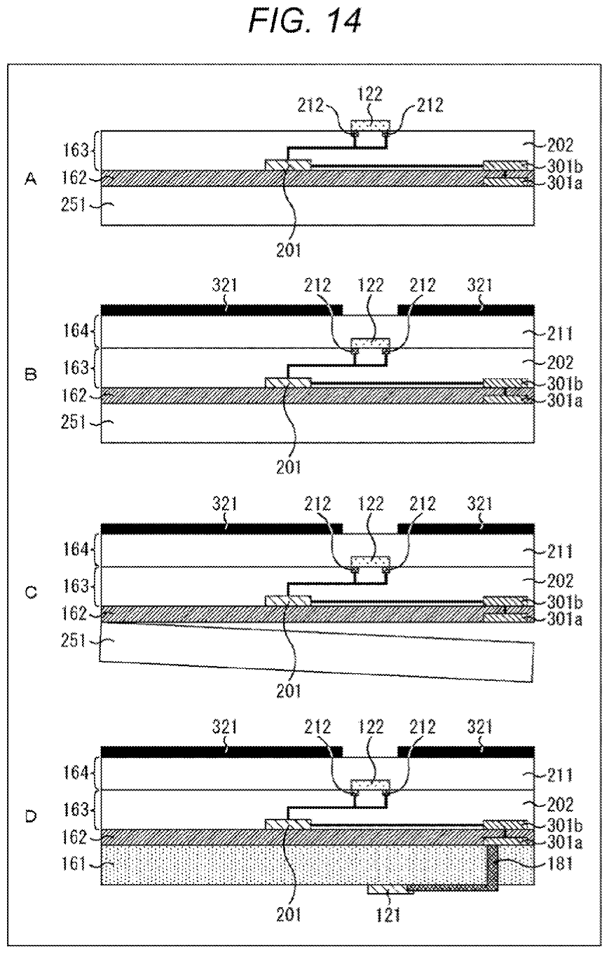

A method for manufacturing the display module 51 according to the first modification will be described with reference to FIG. 14.

First, as illustrated in A of FIG. 14, the support substrate 162 is formed on a glass substrate 251, and the multilayer wiring layer 163 is formed on the support substrate 162. The electrode 212 is formed on the upper surface of the multilayer wiring layer 163, and the LED array 122 is formed on the multilayer wiring layer 163 to be connected to the electrode 212.

Next, as illustrated in B of FIG. 14, the LED array 122 is sealed by the sealing film 211. Moreover, the black layer 321 is formed in the form of an opening at a position corresponding to the LED array 122.

Next, a laminate, which includes the glass substrate 251, the support substrate 162, the multilayer wiring layer 163, the element layer 164, and the black layer 321, is irradiated with a laser beam from the glass substrate 251 side. As illustrated in C of FIG. 14, the glass substrate 251 is peeled from the support substrate 162 by the irradiation with the laser beam.

Then, as illustrated in D of FIG. 14, the PCB substrate 161, where the through electrode 181 and the LED driver 121 are formed, and the support substrate 162 are bonded to each other. For example, a prepreg substrate is used to bond the PCB substrate 161 and the support substrate 162. A Buried Bump Interconnection Technology (B2it) method may be used to bond the PCB substrate 161 and the support substrate 162. As described above, the display module 51 is completed.

As described above, the signal pads 301a, 301b for electrically connecting the PCB substrate 161 and the multilayer wiring layer 163 can be formed on the front surface and the back surface of the support substrate 162, respectively.

Example in which Support Substrate 162 is not Formed

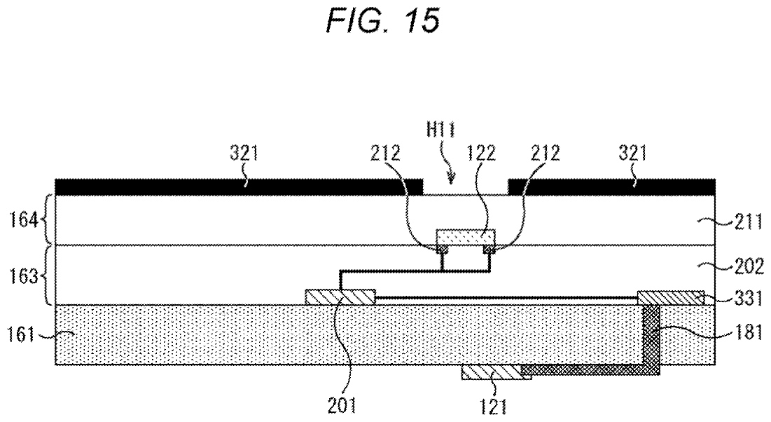

FIG. 15 is a cross-sectional view illustrating a second modification of the display module 51.

In the structure of the display module 51 described with reference to FIG. 14 and the like, the support substrate 162 has been formed, but in the display module 51 according to the second modification of FIG. 15, the PCB substrate 161 and the multilayer wiring layer 163 are joined without the support substrate 162 interposed therebetween. Here, the through electrode of the PCB substrate 161 is connected to the wiring layer 201 via a signal pad 331 formed in the multilayer wiring layer 163.

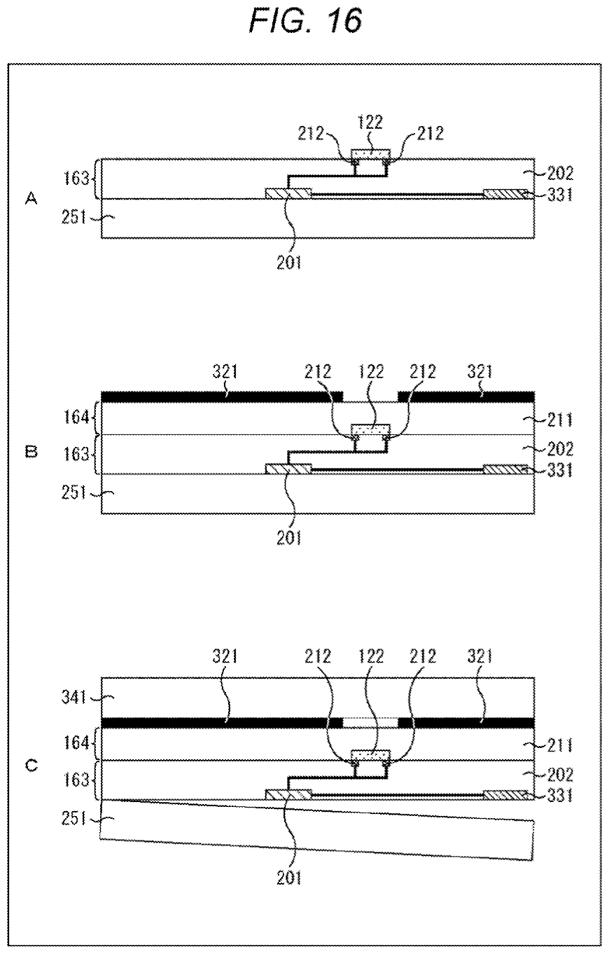

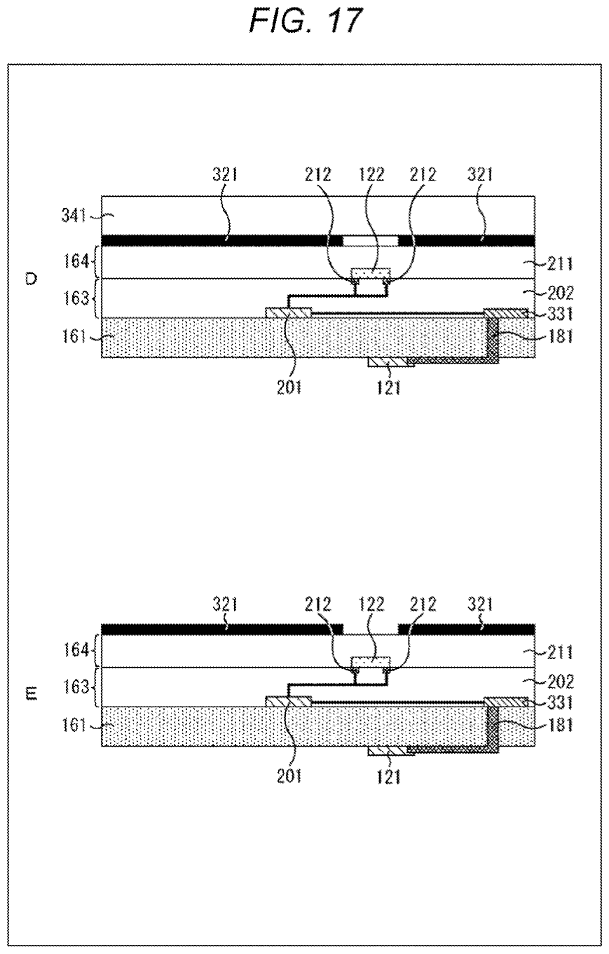

A method for manufacturing the display module 51 according to the second modification will be described with reference to FIGS. 16 and 17.

First, as illustrated in A of FIG. 16, the multilayer wiring layer 163 is formed on the glass substrate 251. The electrode 212 is formed on the upper surface of the multilayer wiring layer 163, and the LED array 122 is formed on the multilayer wiring layer 163 to be connected to the electrode 212.

Next, as illustrated in B of FIG. 16, the LED array 122 is sealed by the sealing film 211. Moreover, the black layer 321 is formed on the element layer 164 in the form of an opening at a position corresponding to the LED array 122.

Next, as illustrated in C of FIG. 16, a support substrate 341 and the black layer 321 are bonded to each other. For example, an adhesive (not illustrated) is used to bond the support substrate 253 and the black layer 321. Here, as the support substrate 341, for example, a glass substrate or a PET film is used.

Thereafter, a laminate, which includes the glass substrate 251, the multilayer wiring layer 163, the element layer 164, and the black layer 321, is irradiated with a laser beam from the glass substrate 251 side. The glass substrate 251 is peeled from the multilayer wiring layer 163 by the irradiation with the laser beam.

Subsequently, as illustrated in D of FIG. 17, the PCB substrate 161, where the through electrode 181 and the LED driver 121 are formed, and the multilayer wiring layer 163 are bonded to each other. For example, a prepreg substrate or a B2it method is used to bond the PCB substrate 161 and the multilayer wiring layer 163.

Then, as illustrated in E of FIG. 17, the support substrate 341 is removed. Note that the support substrate 341 is removed as necessary, and it is also possible for the display module 51 to have a structure with the support substrate 341 remaining. As described above, the display module 51 is completed.

As described above, the display module 51 can be manufactured by peeling the resin layer from the glass substrate 251 and further joining the resin layer to the PCB substrate 161 while the resin layer is supported using the support substrate 341 as an interposer substrate.

Example in which Surface of Display Module 51 on Support Substrate 162 Side is Used as Light Extraction Surface

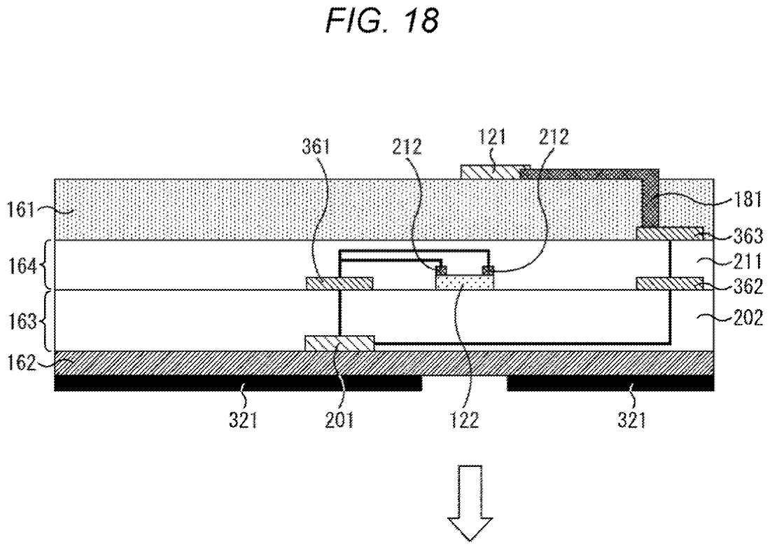

FIG. 18 is a cross-sectional view illustrating a third modification of the display module 51.

In the structure of the display module 51 described in FIG. 14 and the like, the PCB substrate 161 has been joined to the support substrate 162, and the black layer 321 has been formed on the element layer 164. In contrast, in the display module 51 according to the third modification of FIG. 18, the PCB substrate 161 is bonded to the element layer 164, and the black layer 321 is formed on the lower surface side of the support substrate 162. In this case, as indicated by an outlined arrow, the light of each of the LEDs included in the LED array 122 is emitted from the support substrate 162 side of the display module 51.

In the element layer 164, the electrode 212 is formed on the LED array 122, and the electrode 212 is connected to an LED pad 361, which is formed on the lower surface of the element layer 164, via wiring. The LED pad 361 is connected to the wiring layer 201 of the multilayer wiring layer 163 via wiring.

Furthermore, a signal pad 362 is formed on the lower surface of the element layer 164, and the signal pad 362 is connected to the wiring layer 201 via wiring. A signal pad 363 is formed on the element layer 164, and the signal pad 363 is connected to the signal pad 362 via wiring. The signal pad 362 is also connected to the LED driver 121 via the through electrode 181. In this manner, the signal pads 362, 363 electrically connect the PCB substrate 161 and the multilayer wiring layer 163.

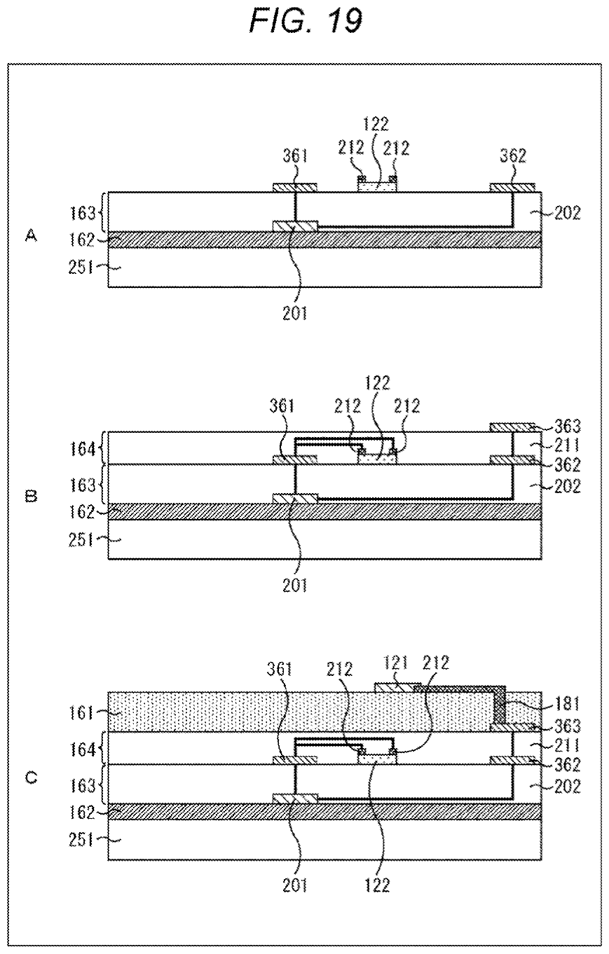

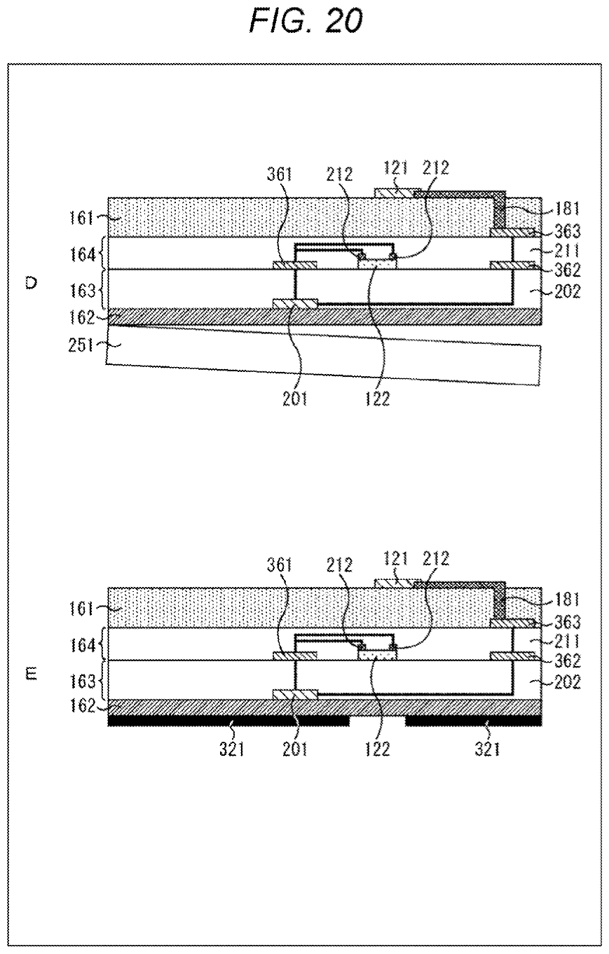

A method for manufacturing the display module 51 according to the third modification will be described with reference to FIGS. 19 and 20.

First, as illustrated in A of FIG. 19, the support substrate 162 is formed on a glass substrate 251, and the multilayer wiring layer 163 is formed on the support substrate 162. The LED array 122, the LED pad 361, and the signal pad 362 are formed on the multilayer wiring layer 163, and the electrode 212 is formed on the LED array 122.

Next, as illustrated in B of FIG. 19, the LED array 122 is sealed by the sealing film 211. Each wiring is formed in the element layer 164, and the signal pad 363 is formed on the element layer 164.

Next, as illustrated in C of FIG. 19, the PCB substrate 161, where the through electrode 181 and the LED driver 121 are formed, and the element layer 164 are bonded to each other. For example, a prepreg substrate or a B2it method is used to bond the PCB substrate 161 and the element layer 164.

Subsequently, a laminate, which includes the glass substrate 251, the support substrate 162, the multilayer wiring layer 163, the element layer 164, and the PCB substrate 161, is irradiated with a laser beam from the glass substrate 251 side. As illustrated in D of FIG. 20, the glass substrate 251 is peeled from the support substrate 162 by the irradiation with the laser beam.

Then, as illustrated in E of FIG. 20, the black layer 321 is formed on the lower surface side of the support substrate 162 in the form of an opening at a position corresponding to the LED array 122. As described above, the display module 51 is completed.

As described above, it is possible for the display module 51 to have a bottom emission structure in which the support substrate 162 side is the light extraction surface.

Example in which Micronized LED Driver is Formed in Element Layer 164

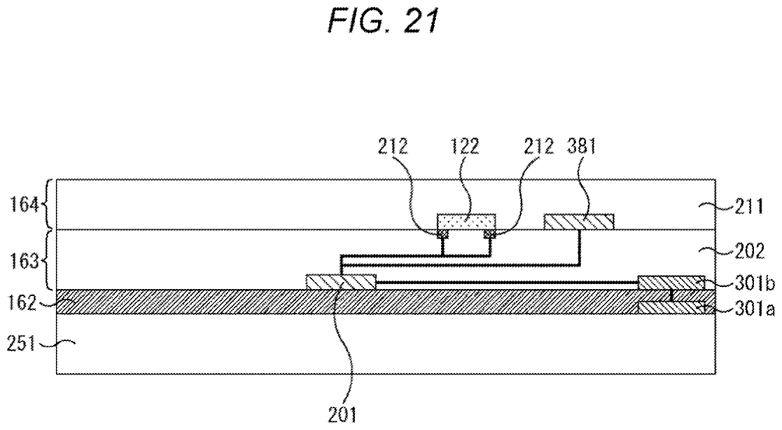

FIG. 21 is a cross-sectional view illustrating a modification of the laminate before being bonded to the PCB substrate 161.

In the structure of the display module 51 described with reference to FIG. 13 and the like, the LED driver 121 has been formed on the PCB substrate 161. In contrast, in a laminate including the support substrate 162, the multilayer wiring layer 163, and the element layer 164, which are included in the display module 51 according to the modification of FIG. 21, an LED driver 381 is formed in the element layer 164.

The LED driver 381 includes, for example, a micronized Si-Driver. The LED driver 381 is connected to the wiring layer 201 of the multilayer wiring layer 163 via wiring.

In this case, a part of the function of the circuit using the TFT included in the wiring layer 201 is transferred to the LED driver 381, and the circuit using the TFT has a simple structure. Since the Si-Driver has higher performance than the circuit using the TFT, it is possible to improve the performance of the entire display module 51 for driving the LED by transferring a part of the function of the circuit using the TFT to the LED driver 381.

### Others

In the present specification, a system is intended to mean a set of a plurality of components (devices, modules (parts), etc.), and it does not matter whether or not all the components are in the same housing. Therefore, a plurality of devices accommodated in separate housings and connected via a network and one device in which a plurality of modules is accommodated in one housing are both systems.

Note that the effects described in the present specification are merely examples and are not limited, and there may be other effects.

Embodiments of the present technology are not limited to the embodiment described above, and various modifications may be made without departing from the gist according to the present technology.

### Examples of Combinations of Configurations

The present technology:

(1)

A display module manufacturing method including:
forming, on a glass substrate, a resin layer in which a plurality of light-emitting elements arranged in an array and first wiring for driving the light-emitting elements are formed; and
joining, before or after peeling the glass substrate from the resin layer, a printed circuit board, on which second wiring for driving the light-emitting elements is formed, to a surface of the resin layer opposite to a light extraction surface.

(2)

The display module manufacturing method according to (1) above, where a circuit using a TFT is formed in the resin layer.

(3)

The display module manufacturing method according to (1) or (2) above, further including:
forming a first support substrate that supports the resin layer on the glass substrate; and
forming the resin layer on the first support substrate.

(4)

The display module manufacturing method according to (3) above, further including:
forming the resin layer on the first support substrate, and then peeling the glass substrate from the first support substrate; and
joining the resin layer and the printed circuit board via the first support substrate.

(5)

The display module manufacturing method according to (3) or (4) above, where a through electrode is formed on the first support substrate as an electrode for electrically connecting the resin layer and the printed circuit board.

(6)

The display module manufacturing method according to (3) or (4) above, where an electrode for electrically connecting the resin layer and the printed circuit board is formed on each of a front surface and a back surface of the first support substrate on the first support substrate.

(7)

The display module manufacturing method according to any one of (1) to (6) above, further including:
forming a second support substrate that supports the resin layer on a side of the light extraction surface of the resin layer, and peeling the glass substrate from the resin layer; and
joining a surface of the resin layer, opposite to the light extraction surface, and the printed circuit board.

(8)

The display module manufacturing method according to any one of (1) to (3) above, where
the resin layer is formed by laminating a wiring layer, in which the first wiring is formed, and an element layer, in which the light-emitting element is formed, and
the wiring layer is formed on the glass substrate, and the element layer is formed on the wiring layer.

(9)

The display module manufacturing method according to (8) above, further including joining the printed circuit board to the element layer.

(10)

The display module manufacturing method according to (9) above, where a pad for electrically connecting the wiring layer and the printed circuit board is formed on the element layer.

(11)

The display module manufacturing method according to any one of (8) to (10) above, where a driver that drives the light-emitting element is formed in the element layer.

(12)

A display module manufacturing method according to any one of (1) to (10) above, where a driver that drives the light-emitting element is formed on a side of the printed circuit board opposite to a surface joined to the resin layer.

(13)

The display module manufacturing method according to any one of (1) to (11) above, where the light-emitting element is a micro-LED.

(14)

The display module manufacturing method according to any one of (1) to (13) above, where the printed circuit board includes a two-layer through substrate.

(15)

The display module manufacturing method according to any one of (1) to (14) above, further including forming, on a side of the light extraction surface of the resin layer, a light absorbing layer that absorbs external light applied from an outside and has an opening formed to emit light of the light-emitting element to the side of the light extraction surface.

(16)

A display module formed by:
forming, on a glass substrate, a resin layer in which a plurality of light-emitting elements arranged in an array and first wiring for driving the light-emitting elements are formed; and
joining, before or after peeling the glass substrate from the resin layer, a printed circuit board, on which second wiring for driving the light-emitting elements is formed, to a side of the resin layer opposite to a light extraction surface.

(17)

The display module according to (16) above, where the display module forms a tiling display.

(18)

A display module including:
a resin layer in which a plurality of light-emitting elements arranged in an array and first wiring for driving the light-emitting elements are formed; and
a printed circuit board that includes a two-layer through substrate in which second wiring for driving the light-emitting elements is formed.

(19)

The display module according to (18) above, where the display module forms a tiling display.

### REFERENCE SIGNS LIST

11 Display system
51 Display module
121 LED driver
122 LED array
141B, 141G, 141R LED chip
161 PCB substrate
162 Support substrate
163 Multilayer wiring layer
164 Element layer
181 Through electrode
191 Connection conductor
201 Wiring layer
202 Resin
203 Signal pad
211 Sealing film
212 Electrode
251 Glass substrate
252 Adhesive
253 Support substrate
301a, 301b Electrode
321 Black layer
331 Signal pad
361 LED pad
362, 363 Signal pad
381 LED driver

1. A display module manufacturing method comprising:
forming, on a glass substrate, a resin layer in which a plurality of light-emitting elements arranged in an array and first wiring for driving the light-emitting elements are formed; and
joining, before or after peeling the glass substrate from the resin layer, a printed circuit board, on which second wiring for driving the light-emitting elements is formed, to a surface of the resin layer opposite to a light extraction surface.

2. The display module manufacturing method according to claim 1, wherein a circuit using a TFT is formed in the resin layer.

3. The display module manufacturing method according to claim 1, wherein:
forming a first support substrate that supports the resin layer on the glass substrate; and
forming the resin layer on the first support substrate.

4. The display module manufacturing method according to claim 3, wherein:
forming the resin layer on the first support substrate, and then peeling the glass substrate from the first support substrate; and
joining the resin layer and the printed circuit board via the first support substrate.

5. The display module manufacturing method according to claim 3, wherein a through electrode is formed on the first support substrate as an electrode for electrically connecting the resin layer and the printed circuit board.

6. The display module manufacturing method according to claim 3, wherein an electrode for electrically connecting the resin layer and the printed circuit board is formed on each of a front surface and a back surface of the first support substrate on the first support substrate.

7. The display module manufacturing method according to claim 1, wherein:
forming a second support substrate that supports the resin layer on a side of the light extraction surface of the resin layer, and peeling the glass substrate from the resin layer; and
joining a surface of the resin layer, opposite to the light extraction surface, and the printed circuit board.

8. The display module manufacturing method according to claim 1, wherein
the resin layer is formed by laminating a wiring layer, in which the first wiring is formed, and an element layer, in which the light-emitting element is formed, and
the wiring layer is formed on the glass substrate, and the element layer is formed on the wiring layer.

9. The display module manufacturing method according to claim 8, wherein joining the printed circuit board to the element layer.

10. The display module manufacturing method according to claim 9, wherein a pad for electrically connecting the wiring layer and the printed circuit board is formed on the element layer.

11. The display module manufacturing method according to claim 8, wherein a driver that drives the light-emitting element is formed in the element layer.

12. The display module manufacturing method according to claim 1, wherein a driver that drives the light-emitting element is formed on a side of the printed circuit board opposite to a surface joined to the resin layer.

13. The display module manufacturing method according to claim 1, wherein the light-emitting element is a micro-LED.

14. The display module manufacturing method according to claim 1, wherein the printed circuit board includes a two-layer through substrate.

15. The display module manufacturing method according to claim 1, wherein forming, on a side of the light extraction surface of the resin layer, a light absorbing layer that absorbs external light applied from an outside and has an opening formed to emit light of the light-emitting element to the side of the light extraction surface.

16. A display module formed by:
forming, on a glass substrate, a resin layer in which a plurality of light-emitting elements arranged in an array and first wiring for driving the light-emitting elements are formed; and
joining, before or after peeling the glass substrate from the resin layer, a printed circuit board, on which second wiring for driving the light-emitting elements is formed, to a side of the resin layer opposite to a light extraction surface.

17. The display module according to claim 16, wherein the display module forms a tiling display.
